(19) United States
(12) Patent Application Publication
(10) Pub. No.: US 2010/0054514 A1
(43) Pub. Date: Mar. 4, 2010

(54) Electrical Circuit, Electrical Small Appliance, in Particular a Hearing Aid, Having the Electrical Circuit, and Use of the Electrical Circuit for Producing the Electrical Small Appliance

(75) Inventors: Chor Fan Chan, Singapore (SG); Leep Foong Chew, Singapore (SG); Cher Huat Lim, Singapore (SG); Hock Peng Lim, Singapore (SG); Meng Kiang Lim, Singapore (SG); Chow Lan Stella Yap, Singapore (SG)

Correspondence Address: LERNER GREENBERG STEMER LLP, P O BOX 2480, HOLLYWOOD, FL, 33022-2480, US

(73) Assignee: SIEMENS MEDICAL INSTRUMENTS PTE. LTD., Singapore (SG)

(21) Appl. No.: 12/548,602

(22) Filed: Aug. 27, 2009

(30) Foreign Application Priority Data
Aug. 27, 2008 (DE) 10 2008 044 642.4

(51) Int. Cl. H04R 25/00; H05K 1/11; H05K 9/00

(52) U.S. Cl. 381/328; 174/263; 174/350

(57) ABSTRACT

An electrical circuit has a printed circuit board which is lengthened at the side in the form of at least one longitudinal contact projection having at least one electrical conductor track and a solder point disposed at the end of the conductor track. Because of its mechanical flexibility, the contact projection allows flexible contact to be made with other electronic components, with little effort. An electrical circuit such as this is particularly highly suitable for electrical small appliances, in particular for a hearing aid.

### CROSS-REFERENCE TO RELATED APPLICATION

This application claims the priority, under 35 U.S.C. §119, of German application DE 10 2008 044 642.4, filed Aug. 27, 2008; the prior application is herewith incorporated by reference in its entirety.

### BACKGROUND OF THE INVENTION

1. Field of the Invention

The invention relates to an electrical circuit which is particularly suitable for electrical small appliances, for example in the form of a hearing aid.

Electrical appliances generally have a multiplicity of electrical circuits which are electrically connected to one another. Various types of electrical connections are known. By way of example, an electrical circuit may be directly soldered via electrically conductive pins to another electrical circuit.

It is also known for electrical circuits to be connected to one another via flexible line wires, wherein the line wires are soldered at each of their two ends to the two electrical circuits. The flexible line wires make it possible to vary the distance between electrical circuits and to align the electrical circuits variably with respect to one another. However, the line wires represent an additional amount of material and, with soldering at both ends, require an additional labor cost.

German utility model DE 691 11 668 T2 discloses a hearing aid having an electrical circuit whose electrical components are each joined together as modules. Conductor tracks are provided on further, flexible circuit boards, in order to connect the modules, which can be arranged on circuit boards. The conductor tracks on the further, flexible circuit boards connect the respective modules via respective solder connections.

German patent DE 10 2005 006 856 B3, corresponding to U.S. Pat. No. 7,507,920, likewise discloses a hearing aid. This hearing aid has an electrical circuit on a printed circuit board, to which a moving control element is connected. The control element is connected to the printed circuit board by conductor tracks on a further, flexible printed circuit board.

### SUMMARY OF THE INVENTION

It is accordingly an object of the invention to provide an electrical circuit, an electrical small appliance, in particular a hearing aid, having the electrical circuit, and use of the electrical circuit for producing the electrical small appliance which overcomes the above-mentioned disadvantages of the heretofore-known devices and methods of this general type. The invention is thus based on the object of allowing electrical contact to be made with an electrical circuit with little effort but still flexibly.

With the foregoing and other objects in view there is provided, in accordance with the invention, an electrical circuit. The electrical circuit contains a printed circuit board being lengthened at a side in a form of at least one flexible contact projection having at least one electrical conductor track and a solder point disposed at an end of the conductor track. The flexible contact projection is longer than it is broad.

A side extension for a printed circuit board, which is generally provided for most electrical circuits, in the form of at least one flexible contact projection with a conductor track and a solder point allows similarly flexible electrical contact to be made as with the aid of an electrical line wire which is soldered to the printed circuit board, with the development of parts which are present in any case reducing the amount of material and the manufacturing complexity. Furthermore, the effort for soldering is halved, since the contact projection, by virtue of its configuration, is already electrically connected on one side of the electrical circuit.

In order to allow flexibility which is comparable to an electrical line wire and goes beyond simple bending, the contact projection must be longer than it is broad. For example, the contact projection may be twice, five times or ten times as long as it is broad. The mechanical flexibility increases as the length increases in comparison to the width.

The flexibility of the electrical connection capability has the particular advantage that the same electrical circuit can be used in different appliances without further adaptation. In this way, the invention makes it possible, for example, to produce hearing aids of different shape, with the same or similar functions, in a simple manner.

The electrical circuit is particularly highly suitable for producing an electrical small appliance, in particular in the form of a hearing aid, of a mobile telephone or of a radio-based headset for reception and reproduction of speech. In the case of small appliances, it is a particular major advantage to reduce the number of soldering processes.

A solder point which is lengthened over a proportion of the contact projection makes it possible to reuse the solder point when the contact projection is shortened, thus allowing the electrical circuit to be matched particularly easily to different forms of use. For example, it is possible to use the same electrical circuit on the one hand in an appliance in which the contact projections must bridge a connection over a long distance and on the other hand in an appliance which requires a short contact projection, because it has a compact shape.

A multiple electrical connection is often required between components in an appliance. In this case, a plurality of separate contact projections allow greater mechanical flexibility than a broad contact projection with a plurality of conductor tracks. This is particularly advantageous when an electrical connection to another electrical component is intended to be produced from the electrical circuit, which other electrical component moves relative to the circuit during normal use of the appliance.

One particularly compact form is made possible by a contact projection having a multiplicity of conductor tracks. In order on the one hand to make it possible to provide sufficiently physically large solder points for the conductor tracks, while on the other hand nevertheless allowing a narrow end area of the contact projection, the solder points for making electrical contact with the conductor tracks are arranged in a row in the longitudinal direction of the contact projection.

Other features which are considered as characteristic for the invention are set forth in the appended claims.

Although the invention is illustrated and described herein as embodied in an electrical circuit, an electrical small appliance, in particular a hearing aid, having the electrical circuit, and use of the electrical circuit for producing the electrical small appliance, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, perspective view of a hybrid circuit with three contact projections according to the invention;

FIG. 2 is a perspective, enlarged view of a contact projection with an electrical conductor track, and a solder point arranged at the end of the conductor track, for surface plating of an electrical contact;

FIG. 3 is a perspective view of the contact projection with three conductor tracks and a microphone, which is surface-soldered to the three solder points on the conductor tracks;

FIG. 4 is a perspective view of the contact projection with the microphone as shown in FIG. 3;

FIG. 5 is a perspective view analogously to FIG. 2, and shows an enlarged illustration of a further contact projection having a solder point with a plated-through hole;

FIG. 6 is a perspective view analogously to FIG. 3, and shows the contact projection with the microphone, which is soldered to three solder points with plated-through holes;

FIG. 7 is a perspective view of the contact projection with the microphone as shown in FIG. 6 from underneath;

FIG. 8 is a perspective view of the contact projection with the microphone as shown in FIGS. 6 and 7; and

FIG. 9 is a perspective view of a hearing aid.

### DETAILED DESCRIPTION OF THE INVENTION

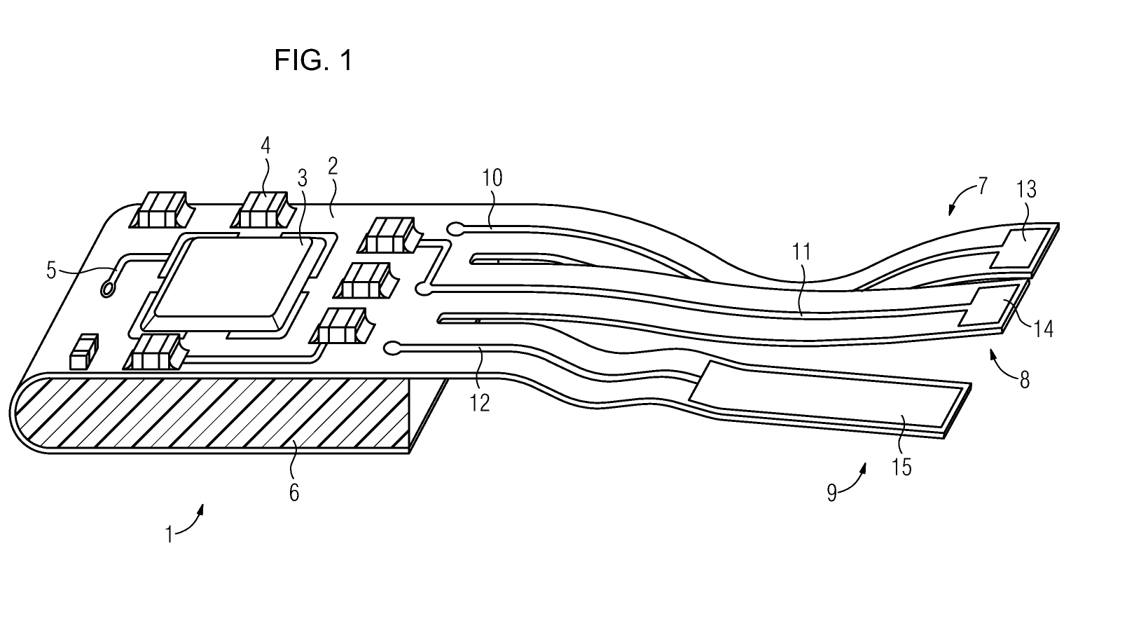

Referring now to the figures of the drawing in detail and first, particularly, to FIG. 1 thereof, there is shown a hybrid circuit 1 with a printed circuit board 2 on which an integrated circuit 3, a number of surface mounted devices (SMD) 4, and a number of conductor tracks 5 are arranged. The printed circuit board 2 is bent through 180° at one point and, from two sides, encloses an area which is encapsulated with plastic 6 and in which further electrical components are arranged, which likewise also govern the function of the hybrid circuit 1.

An upper part of the printed circuit board 2 is lengthened at the side in the form of three flexible contact projections 7-9, which each have an electrical conductor track 10-12 and, at its end, a solder point 13-15. Electrical contacts can be soldered to the solder points 13-15. The contact projections 7-9 each have comparable mechanical flexibility to that of a conventional line wire. In this exemplary embodiment, the contact projections 7-9 are each particularly flexible, since the ratio of their length to their breadth is approximately ten.

A lower part of the printed circuit board 2, like the upper part, can likewise be lengthened in the form of at least one contact projection.

The embodiment in the form of three separate contact projections 7-9 can be connected particularly flexibly. In contrast to a single broad contact projection with three conductor tracks 10-12, this refinement is particularly flexible. Furthermore, both the distances between and the arrangement of the solder points 13-15 can be varied flexibly relative to one another.

The solder points 13 and 14 of the respective upper two contact projections 7 and 8 are approximately square, in the conventional manner. The solder point 15 on the lower contact projection 9, in contrast, is lengthened over a proportion of the length of the contact projection 9. In this case, this proportion extends over approximately half the contact projection 9. This elongated embodiment of the solder point 15 makes it possible to shorten the contact projection 9 virtually by half since, even when shortened in this way, a sufficient part of the solder point 15 remains.

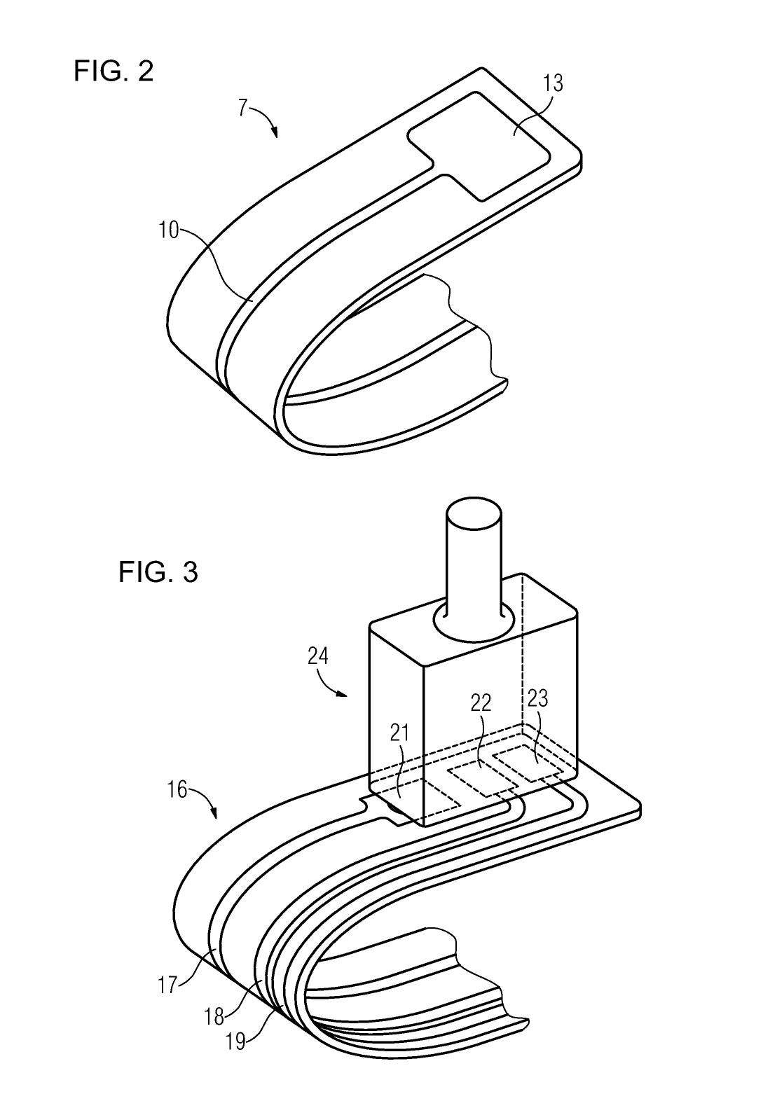

The contact projections 7-9 are suitable both for surface plating and for plated-through holes. FIGS. 2-4 show exemplary embodiments of the contact projections with solder points for surface plating of electrical contacts while, in contrast, FIGS. 5-8 show exemplary embodiments with solder points for plated-through holes.

FIG. 2 shows an enlarged illustration of the upper contact projection 13 from FIG. 1 with the electrical conductor track 10 and the solder point 13, arranged at the end of the conductor track 10, for surface plating of an electrical contact.

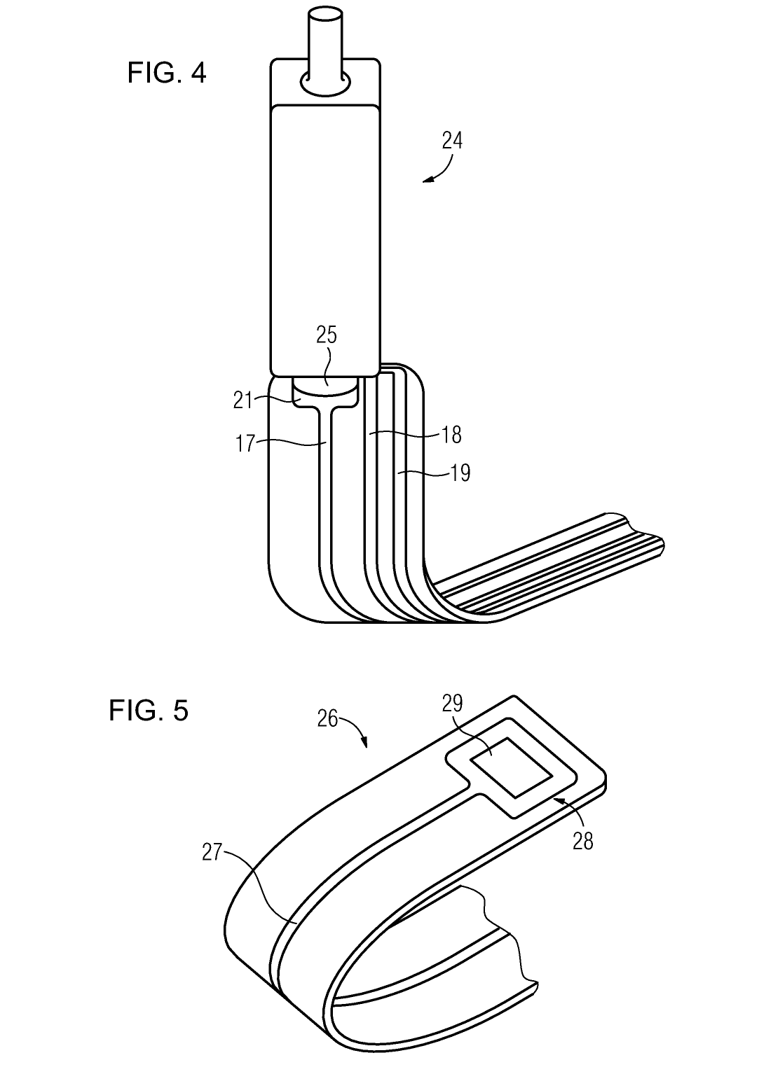

FIGS. 3 and 4 show two different perspectives of a contact projection 16 which has three conductor tracks 17-19 and is therefore compact in comparison to three individual contact projections 7-9 as shown in FIG. 1. The conductor tracks 17-19 end at three solder points 21-23 on which a microphone 24 is soldered to a solder 25 which is applied to the surface of the solder points 21-23.

The arrangement of the solder points 21-23 at the end of the conductor tracks 17-19 in the longitudinal direction of the contact projection 16 allows a particularly compact configuration. If, in contrast, the solder points 21-23 were to be diagonal with respect to the longitudinal direction of the contact projection 16, then the latter would have to be approximately twice as broad at its end.

This embodiment with the microphone 24, the compact contact projection 16 and the solder points 21-23 arranged longitudinally in a row is particularly suitable for hearing aids, which combine electrical components in a small area.

FIG. 5 shows an enlarged illustration of a contact projection 26 which, in contrast to the contact projection 7 shown in FIG. 2, has a solder point 28 with a plated-through hole 29. The solder point 28 is electrically connected via a conductor track 27 to an hybrid circuit 1.

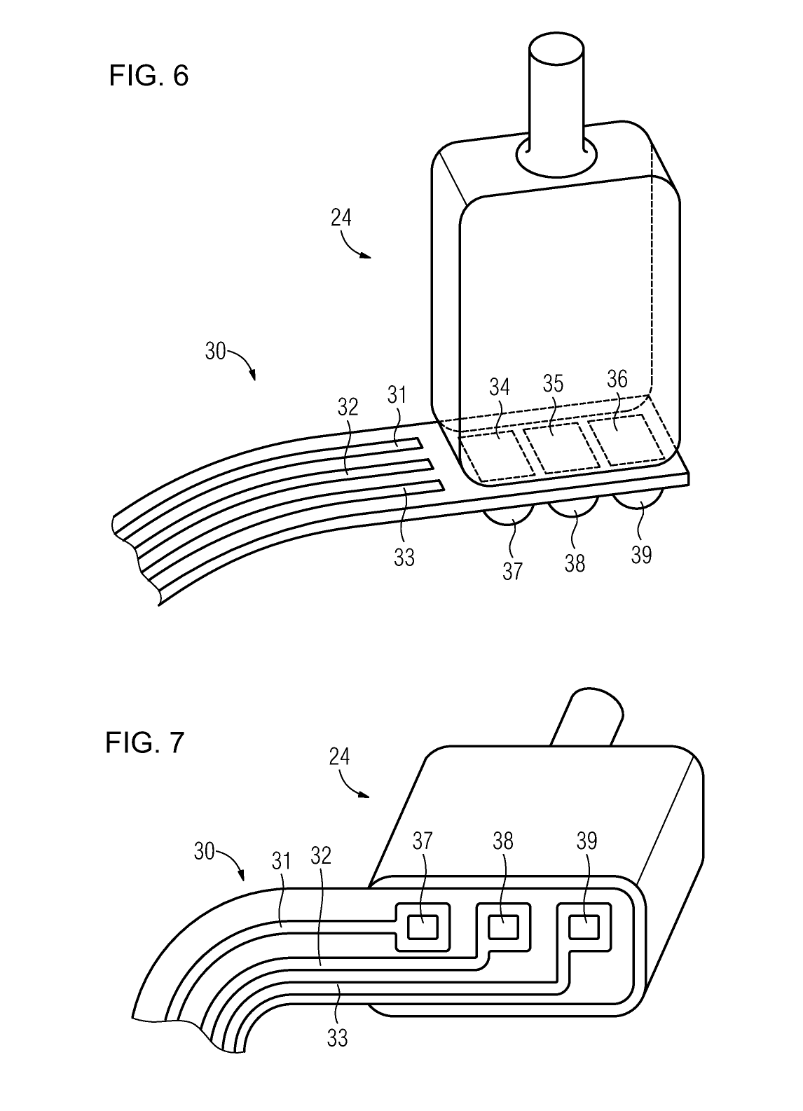

FIGS. 6-8 each show, from a different illustration perspective, a contact projection 30 with three conductor tracks 31-33, at whose respective end a solder point 34-36 is provided. The solder points 34-36 each have a plated-through hole, each of which is filled with solder 34-36 for attachment of a microphone 24.

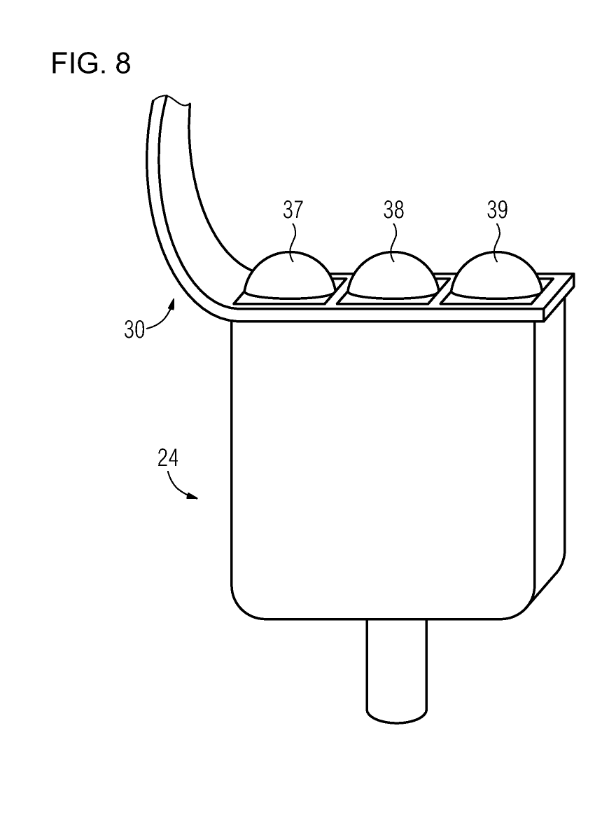

FIG. 6 corresponds to a perspective from the side and from above, FIG. 7 essentially from underneath, and FIG. 8 essentially from the side.

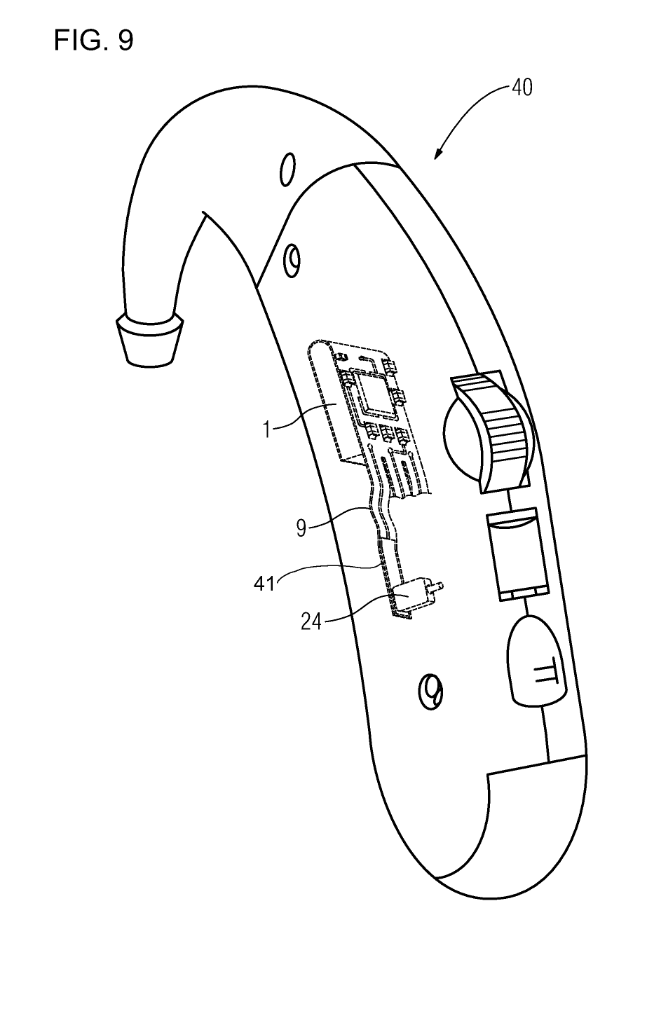

FIG. 9 shows a hearing aid 40 which, because of its small housing volume, is particularly highly suitable for use of an electrical circuit according to one of the embodiments described above.

The flexible contact projections 7-9, 16, 26 may additionally be provided with a shield against electromagnetic interference. The shield reduces electromagnetic interference from the current flow in the contact projections 7-9, 16, 26. This interference can be expressed, for example, by noise or other interference in a hearing aid 40. Since the compact form of hearing aids 40 often allows electromagnetic interference to occur, this refinement is particularly advantageous for hearing aids 40. The electromagnetic shield is provided, for example, by a silver paste 41 or by lamination of the flexible contact projections 7-9, 16, 26 with a silver sheet.

At least one embodiment of the invention relates, in summary, to an electrical circuit having a printed circuit board which is lengthened at the side in the form of at least one flexible contact projection having at least one electrical conductor track and a solder point, which is arranged at the end of the conductor track. Because of its mechanical flexibility, the contact projection allows flexible contact to be made with other electronic components, with little effort. An electrical circuit such as this is particularly highly suitable for electrical small appliances, in particular for a hearing aid.

1. An electrical circuit, comprising:
a printed circuit board being lengthened at a side in a form of at least one flexible contact projection having at least one electrical conductor track and a solder point disposed at an end of said conductor track, said flexible contact projection being longer than it is broad.

2. The electrical circuit according to claim 1, wherein said solder point is lengthened over a proportion of a length of said flexible contact projection such that its length along said flexible contact projection is at least twice as great as its width transversely with respect to said flexible contact projection.

3. The electrical circuit according to claim 1, wherein said solder point is lengthened at least over half a longitudinal extent of said flexible contact projection.

4. The electrical circuit according to claim 1, wherein said flexible contact projection is one of a multiplicity of flexible contact projections.

5. The electrical circuit according to claim 1, wherein said flexible contact projection has a multiplicity of conductor tracks, at whose respective end said solder point is disposed.

6. The electrical circuit according to claim 5, wherein said solder points are disposed in a row at an end of said conductor track in a longitudinal direction of said flexible contact projection.

7. The electrical circuit according to claim 1, wherein the electrical circuit is a hybrid circuit.

8. The electrical circuit according to claim 7, wherein said hybrid circuit supports functions of a hearing aid.

9. The electrical circuit according to claim 8, wherein said hybrid circuit supports an operation of a microphone with which electrical contact is made via said flexible contact projection.

10. The electrical circuit according to claim 1, wherein said at least one flexible contact projection has a shield for shielding against electromagnetic interference.

11. The electrical circuit according to claim 10, wherein said shield is in a form of a silver paste, which is applied to said flexible contact projection.

12. The electrical circuit according to claim 10, wherein said shield is formed by a lamination of said flexible contact projections with a silver sheet.

13. An electrical small appliance, comprising:
an electrical circuit containing a printed circuit board being lengthened at a side in a form of at least one flexible contact projection having at least one electrical conductor track and a solder point disposed at an end of said conductor track, said flexible contact projection being longer than it is broad.

14. The electrical small appliance according to claim 13, wherein the electrical small appliance is a hearing aid.

15. A method of using an electrical circuit, which comprises the step of:
providing, in an electrical small appliance, the electrical circuit containing a printed circuit board being lengthened at a side in a form of at least one flexible contact projection having at least one electrical conductor track and a solder point disposed at an end of said conductor track, said flexible contact projection being longer than it is broad.

16. The method according to claim 15, which further comprises producing the electrical small appliance in a form of a hearing aid.
